(19) United States
(12) Patent Application Publication
(10) Pub. No.: US 2025/0155511 A1
(43) Pub. Date: May 15, 2025

(54) BATTERY VOLTAGE MONITORING SEMICONDUCTOR INTEGRATED CIRCUIT AND ELECTRONIC CIRCUIT SYSTEM

(71) Applicant: Yoichi TAKANO, Hadano-shi (JP)

(72) Inventor: Yoichi TAKANO, Hadano-shi (JP)

(73) Assignee: MITSUMI ELECTRIC CO., LTD., Tokyo (JP)

(21) Appl. No.: 18/944,028

(22) Filed: Nov. 12, 2024

(30) Foreign Application Priority Data
Nov. 14, 2023 (JP) 2023-193787

(51) Int. Cl. G01R 31/3835; G01R 31/36

(52) U.S. Cl. CPC G01R 31/3835; G01R 31/3648

(57) ABSTRACT

Disclosed is a battery voltage monitoring semiconductor integrated circuit, including: a voltage input terminal to receive an input of a voltage from a monitored battery; a voltage dividing circuit that includes a plurality of series resistors to divide a voltage at the voltage input terminal; an output terminal that outputs a voltage corresponding to a voltage obtained by the voltage dividing circuit dividing the voltage at the voltage input terminal; a voltage buffer circuit connected between a connection node of the plurality of series resistors and the output terminal; and a clamp circuit that clamps a potential at the connection node of the plurality of series resistors.

### REFERENCE TO RELATED APPLICATIONS

This application is based upon and claims the benefit of priority from the prior Japanese Patent Application No. 2023-193787 filed on Nov. 14, 2023, the entire contents of which are incorporated herein by reference.

### TECHNICAL FIELD

The present invention relates to a battery voltage monitoring semiconductor integrated circuit that generates and outputs a voltage for monitoring a battery voltage in an electronic circuit system provided with large-scale integration (LSI) that operates using a voltage from a battery as a power source, and to an electronic circuit system that uses the same.

### DESCRIPTION OF RELATED ART

In recent years, automobiles have been equipped with electronic devices such as car audio and navigation systems, and electronic circuit systems that include microcomputers (or micro controller units, MCUs) for controlling the electronic devices. For these electronic devices and electronic circuit systems, a voltage stepped down from a battery by a DC-DC comparator or the like is supplied as the power supply voltage.

However, the voltage of the automobile battery is unstable, which can result in instances where the battery voltage drops during operation. This may cause the system to malfunction or run out of control. Therefore, it is necessary for the microcomputer to immediately know when the power supply voltage drops below a predetermined level by monitoring the power supply voltage. Typically, the battery used in an in-vehicle system operates at a voltage of 12 V to 18 V, and a voltage stepped down to, for example, 3.3 V by a DC-DC comparator or the like is supplied to the microcomputer.

There is a technology that uses a reset IC to reset a microcomputer. The reset IC generates a reset signal when the power supply voltage drops below a predetermined level by monitoring the power supply voltage. For example, JP 2022-129021A discloses an invention relating to such a reset IC and a system that uses the reset IC to detect a drop in battery voltage to reset a microcomputer.

There is also a method for monitoring the battery voltage using a microcomputer. In this method, a microcomputer with a built-in AD converter is used, and a voltage obtained by dividing the battery voltage by series resistors is input to an I/O port for the built-in AD converter.

Furthermore, there is an invention relating to a semiconductor integrated circuit, in place of a microcomputer, that has a function of monitoring the state of the battery voltage (for example, WO 2010/074290).

### SUMMARY OF THE INVENTION

The reset IC described in JP 2022-129021A detects a drop or an overvoltage in battery voltage to generate a reset signal by using a comparator. The comparator compares a voltage obtained by dividing the monitored power supply voltage (battery voltage) by series resistors with a reference voltage. As this is a method for monitoring the microcomputer, there is a problem in that while the battery voltage can be monitored instantaneously, it is not possible to monitor the battery voltage constantly.

In the case of an automobile battery, the battery may be disconnected due to, for example, disconnection of a cord caused by vibration of the vehicle body or the like. If the battery is disconnected, a phenomenon called load dump may occur, which causes the battery voltage to surge, resulting in an overvoltage state. Therefore, for the technique of monitoring the battery voltage by the microcomputer, if a voltage obtained by dividing the battery voltage by series resistor is input to the I/O port of the microcomputer for the AD converter, there is a problem in that an element of the I/O port may be damaged due to an overvoltage caused by a surge in battery voltage.

This invention was made with the above-mentioned problems in mind. An object of the present invention is to provide a battery voltage monitoring semiconductor integrated circuit that is capable of performing constant monitoring by a microcomputer and precise monitoring of a battery voltage, and an electronic circuit system that uses the same.

Another object of the present invention is to provide a battery voltage monitoring semiconductor integrated circuit that is capable of preventing damage to an element of an I/O port of a microcomputer when a battery voltage surges, and an electronic circuit system that uses the same.

To achieve at least one of the abovementioned objects, a battery voltage monitoring semiconductor integrated circuit reflecting one aspect of the present invention comprises: a voltage input terminal to receive an input of a voltage from a monitored battery; a voltage dividing circuit that includes a plurality of series resistors to divide a voltage at the voltage input terminal; an output terminal that outputs a voltage corresponding to a voltage obtained by the voltage dividing circuit dividing the voltage at the voltage input terminal; a voltage buffer circuit connected between a connection node of the plurality of series resistors and the output terminal; and a clamp circuit that clamps a potential at the connection node of the plurality of series resistors.

### BRIEF DESCRIPTION OF DRAWINGS

The advantages and features provided by one or more embodiments of the invention will become more fully understood from the detailed description given hereinbelow and the appended drawings which are given by way of illustration only, and thus are not intended as a definition of the limits of the present invention, wherein:

FIG. 1 is a circuit configuration diagram illustrating a battery voltage monitoring semiconductor integrated circuit according to an embodiment of the present invention, and a suitable system that uses the semiconductor integrated circuit;

FIG. 2 is a circuit configuration diagram illustrating the battery voltage monitoring semiconductor integrated circuit according to the embodiment of the present invention;

FIG. 3 is a circuit configuration diagram illustrating a buffer circuit that constitutes the battery voltage monitoring semiconductor integrated circuit according to the embodiment;

FIG. 4 is a circuit configuration diagram illustrating a clamp circuit that constitutes the battery voltage monitoring semiconductor integrated circuit according to the embodiment;

FIG. 5A is a graph showing the relationship between a monitored battery voltage and, as an example, an output voltage divided to be one-sixth of the battery voltage when a clamp circuit is absent from the battery voltage monitoring semiconductor integrated circuit according to the embodiment;

FIG. 5B is a graph showing the relationship between the battery voltage and the output voltage divided to be one-sixth of the battery voltage when a clamp circuit is provided in the battery voltage monitoring semiconductor integrated circuit according to the embodiment;

FIG. 6 is a circuit diagram illustrating the configuration of a conventional, general battery voltage monitoring circuit;

FIG. 7 is a circuit diagram illustrating an internal voltage generating circuit when the internal voltage generating circuit is provided as a variation of the battery voltage monitoring semiconductor integrated circuit according to the embodiment;

FIG. 8A is a circuit configuration diagram illustrating a variation of the battery voltage monitoring semiconductor integrated circuit according to the embodiment; and

FIG. 8B is a circuit configuration diagram illustrating a variation of the battery voltage monitoring semiconductor integrated circuit according to the embodiment.

### DETAILED DESCRIPTION

Hereinafter, one or more suitable embodiments of the present invention will be described with reference to the drawings.

FIG. 1 shows a suitable system using a battery voltage monitoring semiconductor integrated circuit (hereinafter referred to as battery voltage monitoring IC) to which the present invention is applied. As shown in FIG. 1, in this system, a DC voltage VBAT of 12 V to 18 V from a battery 11 is stepped down to a low voltage such as 3.3 V by a DC voltage conversion circuit 12 to be supplied to a microcomputer (MCU) 13 and a semiconductor device 14. The DC voltage conversion circuit 12 is a DC-DC comparator, a (low dropout or LDO) regulator, or the like. The semiconductor device 14 is a system-on-a-chip (SoC) or the like mounted on an in-vehicle control board.

In the system shown in FIG. 1, a microcomputer with a built-in AD converter (ADC) is used as the microcomputer 13, and a battery voltage monitoring IC 15 according to the embodiment of the present invention configured to monitor the battery voltage VBAT is provided. An output voltage Vout obtained by dividing an input voltage VIN of the battery voltage monitoring IC 15 to be 1/n of VIN is input to an ADC input terminal I/O (ADC) of the microcomputer 13. When the battery voltage VBAT drops below a predetermined level or becomes an overvoltage, the microcomputer 13 detects the drop or the overvoltage, generates a reset signal RST, and outputs the reset signal RST to the semiconductor device 14.

The microcomputer 13 also generates and outputs a control signal and a set voltage for the battery voltage monitoring IC 15.

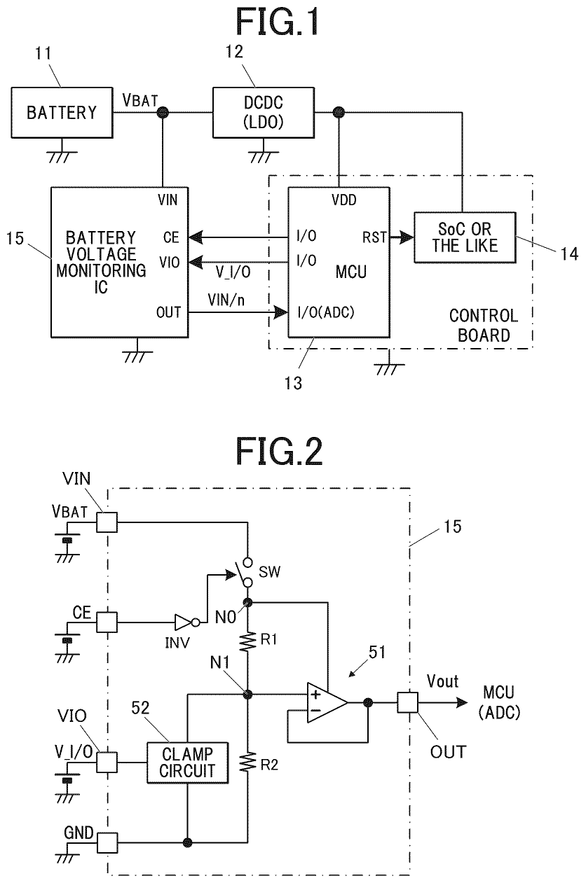

FIG. 2 shows the circuit configuration of the battery voltage monitoring IC 15 according to the embodiment.

As shown in FIG. 2, the battery voltage monitoring IC 15 according to the present embodiment includes a voltage input terminal VIN, a ground terminal GND, a switch element SW, voltage dividing series resistors R1 and R2, and an external terminal CE. The DC voltage VBAT from the battery 11 is input to the voltage input terminal VIN. The switch element SW and voltage dividing series resistors R1 and R2 are connected in series between the voltage input terminal VIN and the ground terminal GND. An enable signal for turning on and off the switch element SW is input to the external terminal CE from the outside. In the present embodiment, although not particularly limited, the switch element SW is turned on and off by a signal obtained by inverting a signal input to the external terminal CE with an inverter INV.

The battery voltage monitoring IC 15 includes a voltage buffer circuit 51, a voltage output terminal OUT, a clamp circuit 52, and an external terminal VIO. The voltage buffer circuit 51 includes a voltage follower with an input terminal connected to a connection node N1 of the voltage dividing resistors R1 and R2. The voltage output terminal OUT outputs the output voltage Vout of the voltage buffer circuit 51 to the outside. The clamp circuit 52 clamps the potential at the connection node N1 of the voltage dividing resistors R1 and R2. A set voltage V_I/O, which is input to the clamp circuit 52, is input to the external terminal VIO. The set voltage V_I/O is set by the microcomputer 13 or the like to a suitable potential according to the system to which the present invention is applied.

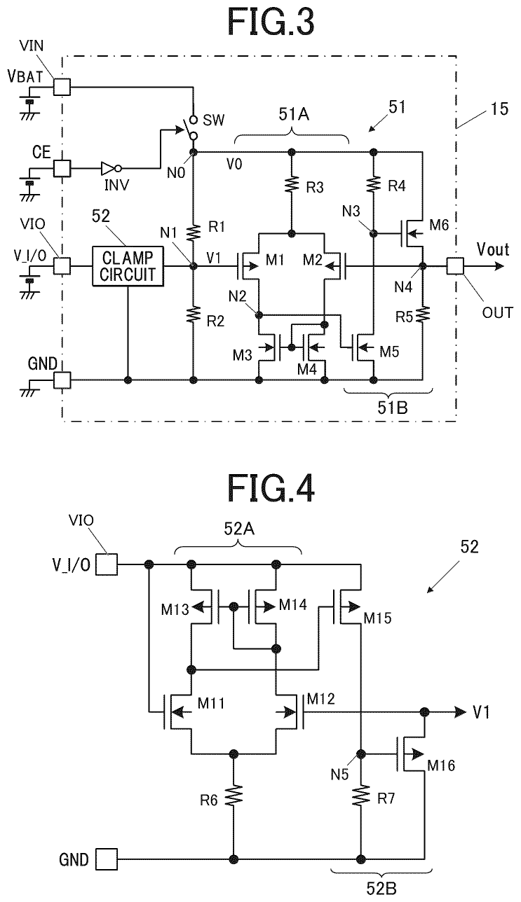

FIG. 3 shows a specific example of the voltage buffer circuit 51 that constitutes the battery voltage monitoring IC 15 according to the present embodiment.

As shown in FIG. 3, the voltage buffer circuit 51 according to the present embodiment includes an input stage 51A. The input stage 51A includes a pair of differential input p-channel metal oxide semiconductor (PMOS) transistors M1 and M2, current mirror n-channel metal oxide semiconductor (NMOS) transistors M3 and M4, and a resistor R3 for a constant current. The current mirror NMOS transistors M3 and M4 are connected between the drain terminals of the transistors M1 and M2 and a grounding point. The resistor R3 is connected between a connection node N0 of the switch element SW and resistor R1 and the common source terminal of the differential input PMOS transistors M1 and M2. The voltage V1 at the connection node N1 of the voltage dividing resistors R1 and R2 is input to the gate terminal of the transistor M1. Instead of the resistor R3, a constant current source using a constant voltage source, and a current mirror circuit may be used, for example.

Furthermore, the voltage buffer circuit 51 includes an output stage 51B. The output stage 51B includes resistors R4 and R5, and NMOS transistors M5 and M6. The resistor R4 and the NMOS transistor M5 are connected in series between the connection node N0 of the switch element SW and resistor R1 and a grounding point. The NMOS transistor M6 is connected with R4 and M5 to form a source follower. The potential at a connection node N2 of the transistors M1 and M3 of the input stage 51A is applied to the gate terminal of the transistor M5. Similarly to the resistor R3, a constant current source may be used instead of the resistor R4.

The gate terminal of the transistor M6 of the output stage 51B is connected to a connection node N3 of the resistor R4 and transistor M5. A connection node N4 of the transistor M6 and resistor R5 is connected to the output terminal OUT. The potential at the connection node N4 is applied to the gate terminal of the differential input transistor M2 of the input stage 51A. As the voltage buffer circuit 51 has the same configuration and the same function as a general differential amplifier circuit, a detailed description of its operation is not provided here.

As described above, the voltage buffer circuit 51 is provided in the battery voltage monitoring IC 15 according to the present embodiment. This reduces the output impedance, thereby reducing the influence of noise due to wiring routing.

FIG. 4 shows a specific example of the clamp circuit 52 that constitutes the battery voltage monitoring IC 15 according to the present embodiment.

As shown in FIG. 4, the clamp circuit 52 according to the present embodiment includes an input stage 52A. The input stage 52A includes a pair of differential input NMOS transistors M11 and M12, current mirror PMOS transistors M13 and M14, and a resistor R6 for a constant current. The current mirror PMOS transistors M13 and M14 are connected between the drain terminals of the transistors M11 and M12 and the power supply voltage terminal of the circuit. The resistor R6 is connected between the common source terminal of the differential input transistors M11 and M12 and a grounding point. The gate terminal of the transistor M11 is connected to the external terminal VIO to receive the voltage V_I/O from the outside. A constant current source may be used instead of the resistor R6.

The clamp circuit 52 according to the present embodiment includes an amplifier circuit, and an output stage 52B. The amplifier circuit includes a PMOS transistor M15 and a resistor R7 connected in series between the power supply voltage terminal of the circuit and a grounding point. The output stage 52B includes a PMOS transistor M16 to which the potential at a connection node N5 of the drain terminal of the transistor M15 and the resistor R7 is applied. The clamp circuit 52 according to the present embodiment operates with the voltage V_I/O at the external terminal VIO as the power supply voltage. However, for the power supply voltage for the differential input stage 52A and output stage 52B of the clamp circuit 52, the voltage V0 at the node N0 may be used. The voltage V0 at the node N0 is the voltage at the voltage input terminal VIN supplied via the switch SW. A constant current source may be used instead of the resistor R7.

In the clamp circuit 52 with the above configuration, the differential input stage 52A drives the transistors M15 and M16 of the output stage 52B in such a way that the gate voltage of the transistor M12 matches the gate voltage of the transistor M11, which is equal to the voltage V_I/O at the external terminal VIO. As a result, when the voltage V1 at the connection node N1 of the voltage dividing resistors R1 and R2 in FIG. 3, to which the source terminal of the transistor M16 is connected, is about to rise above the voltage V_I/O, the source current of the transistor M16 is increased, thereby clamping the voltage V1 at the node N1 to V_I/O.

In the present embodiment, although not particularly limited, the differential input stage 52A operates as a differential amplifier with an offset. Specifically, an offset voltage Voff of several 100 mV is set in advance so that V1>V_I/O. This means that V1=V_I/O+Voff, and the output voltage Vout of the battery voltage monitoring IC 15 can vary to the full dynamic range of the AD converter of the microcomputer to which this voltage Vout is input.

More specifically, a differential amplifier generally has an offset voltage ΔV of several hundred mV due to manufacturing variations. If the offset voltage is negative (−ΔV), V1 will be clamped to V_I/O−ΔV unless the offset voltage Voff is set in advance.

In contrast, when the differential input stage 52A is designed to have the offset voltage Voff of several 100 mV in advance as described above, the offset voltage Voff and the offset voltage−ΔV due to manufacturing variations cancel each other, leading to V1=V_I/O. This allows the maximum value of Vout to be the upper limit value of the dynamic range of the AD converter.

On the other hand, when the offset voltage due to manufacturing variations is positive (+ΔV), the clamp voltage V1=V_I/O+Voff+ΔV, and the maximum value of Vout is shifted to a higher value. This allows for effective use of the dynamic range of the AD converter.

Next, advantages of providing the clamp circuit 52 in the IC 15 will be described.

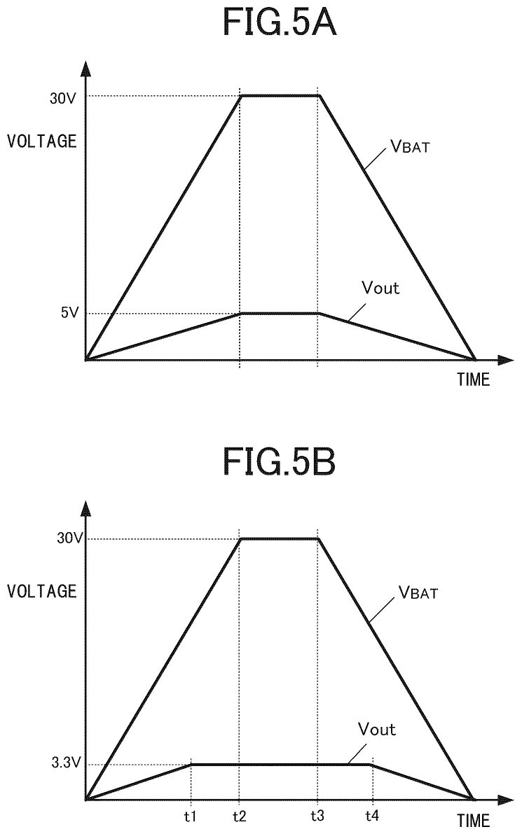

FIG. 5A shows characteristics of the output voltage Vout of the battery voltage monitoring IC in a case where the clamp circuit 52 is not provided, while FIG. 5B shows characteristics of the output voltage Vout of the battery voltage monitoring IC in a case where the clamp circuit 52 is provided. In either case, it is assumed that the resistance ratio of the voltage dividing resistors R1 and R2 is set so that the voltage VBAT (e.g., 30 V) at the input terminal VIN is compressed to one-sixth to obtain the voltage V1 at the node N1.

Now, consider a case where the input voltage VBAT starts from 0 V and rises to 30 V, and falls from 30 V to 0 V after a predetermined time. In this case, when the clamp circuit 52 is not provided, the output voltage Vout increases from 0 V to 5 V and then decreases from 5 V to 0 V after the predetermined time, following the change in the input voltage VBAT, as shown in FIG. 5A. Thus, in the case where VBAT is 30 V, Vout becomes 5 V. However, the microcomputer operates with the power supply voltage of 3.3 V. Therefore, when the voltage Vout of 5 V is input to the ADC input terminal I/O (ADC) of the microcomputer, there is a possibility that an internal element of the microcomputer is destroyed.

On the other hand, considering the case where the input voltage VBAT starts from 0 V and rises to 30 V, and falls from 30 V to 0 V after a predetermined time, when the clamp circuit 52 is provided, the output voltage Vout starts rising from 0 V following the change in the input voltage VBAT, but becomes constant at a time t1, as shown in FIG. 5B. The time t1 is a time at which the output voltage Vout reaches the voltage V_I/O at the external terminal VIO, and a time before a time t2 at which the VBAT reaches 30 V. Also, in the process where the input voltage VBAT decreases, the output voltage Vout starts decreasing from a time t4. The time t4 is a time at which one-sixth of the voltage VBAT reaches V_I/O, and a time after a time t3 at which the VBAT starts decreasing from 30 V.

Thus, when the voltage V_I/O at the external terminal VIO is set to 3.3 V, the upper limit of Vout is 3.3 V even when VBAT=30 V. Therefore, even when Vout is input with VBAT=30 V to the ADC input terminal I/O (ADC) of the microcomputer, which operates with the power supply voltage of 3.3 V, an internal element of the microcomputer will not be destroyed. As a result, when the battery voltage monitoring IC 15 according to the present embodiment is used in the in-vehicle system shown in FIG. 1, even when the voltage VBAT of the battery 11 jumps up due to cranking, load dump, or the like and becomes an overvoltage state, the I/O port of the microcomputer 13 can be protected from the overvoltage by limiting Vout by the clamp circuit 52.

In the battery voltage monitoring IC 15 according to the present embodiment, the switch SW and the external terminal CE, to which a control signal from the switch SW is input, are provided. This makes it possible to prevent a current from constantly flowing through the voltage dividing resistors R1 and R2 by turning off the switch SW. Therefore, it is possible to reduce current consumption and suppress battery depletion.

Furthermore, unlike a system in which a reset IC is used to monitor the battery voltage as described in JP 2022-129021A, a voltage (V1) proportional to the battery voltage VBAT can be input to the microcomputer 13. This allows the microcomputer to constantly monitor the state of the battery and perform processing such as detecting an anomaly, including low voltage, and forecasting battery life.

In addition, the battery voltage monitoring IC 15 according to the present embodiment includes a smaller number of external terminals than the LSI disclosed in WO 2010/074290. This allows for the use of a small package of 5 pins, thereby making it possible to reduce costs and save space.

Moreover, the battery voltage monitoring IC 15 according to the present embodiment has the following advantages as compared with a conventional, general battery voltage monitoring circuit.

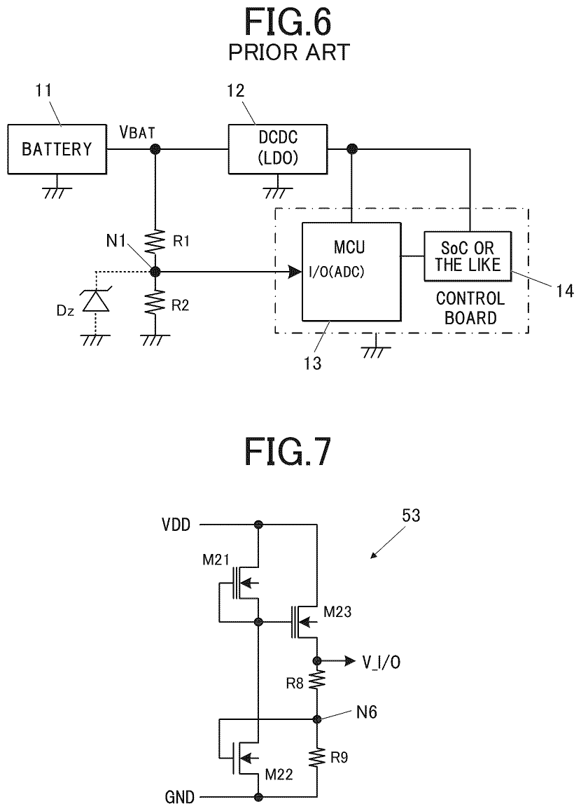

FIG. 6 shows the configuration of a conventional, general battery voltage monitoring circuit.

As shown in FIG. 6, in the case of the conventional battery voltage monitoring circuit, it is common to adopt a configuration in which the series resistors R1 and R2 for dividing the voltage VBAT of the battery 11 are provided at the front stage of the microcomputer 13, and a voltage divided by the resistors R1 and R2 is input to an ADC input terminal I/O (ADC) of the microcomputer 13.

However, in the battery voltage monitoring circuit as shown in FIG. 6, a current constantly flows through the voltage dividing resistors R1 and R2. This gives rise to a problem of large wasteful current consumption. In addition, the resistors R1 and R2 are provided as external resistors using discrete elements, which have large variations. This results in a problem of reduced precision of a monitored voltage input to the microcomputer.

In the case of the conventional battery voltage monitoring circuit, even when the clamp circuit is provided, a Zener diode Dz is generally connected between the connection node N1 of the resistors R1 and R2 and a grounding point. In such a circuit, there are problems in that a leakage current flows through the Zener diode Dz, causing an error in the potential at the node N1, and in that the number of components increases.

Furthermore, when the resistors R1 and R2 are provided using external elements, it is necessary to route wiring to connect the resistor elements. This increases the wiring length, thereby rendering the circuit more susceptible to noise.

On the other hand, according to the battery voltage monitoring IC 15 of the above embodiment with the configuration as shown in FIGS. 2 to 4 and the system that uses the same, the voltage dividing resistors R1 and R2 are on-chip resistor elements. Therefore, as compared with the case of using external elements, the variation of the resistance ratio becomes small, and the precision of the monitored voltage input to the microcomputer becomes high.

In addition, there is no need to route wiring to connect resistors outside the IC. This renders the IC less susceptible to noise.

Furthermore, the external resistors and the Zener diode are not required. This results in an advantage in reducing the number of components, thereby increasing the mounting density of the circuit to achieve miniaturization.

### Variation

Next, variations of the battery voltage monitoring IC 15 according to the above embodiment will be described.

In the battery voltage monitoring IC 15 shown in FIG. 2, the voltage V_I/O input to the clamp circuit 52 is input from the external terminal VIO. On the other hand, in the first variation, by providing a constant voltage circuit that generates the voltage V_I/O inside the IC, the external terminal VIO is omitted to reduce the number of terminals of the IC.

FIG. 7 shows a voltage generating circuit that generates the voltage V_I/O.

The voltage generating circuit in FIG. 7 includes a depletion-mode NMOS transistor M21 and an enhancement-mode NMOS transistor M22 connected in series between the power supply voltage terminal and a grounding point, and a depletion-mode NMOS transistor M23 and series resistors R8 and R9 similarly connected in series between the power supply voltage terminal and the grounding point. The gate terminal and source terminal of the transistor M21 are connected to each other. The gate terminal of the transistor M23 is connected to the source terminal of the transistor M21. The gate terminal of the transistor M22 is connected to a connection node N6 of the resistors R8 and R9. A constant voltage is output from the source terminal of the transistor M23. As a constant voltage circuit with such a configuration is a known circuit as disclosed in, for example, JP 8-30345A, a detailed description of its operation is not provided here.

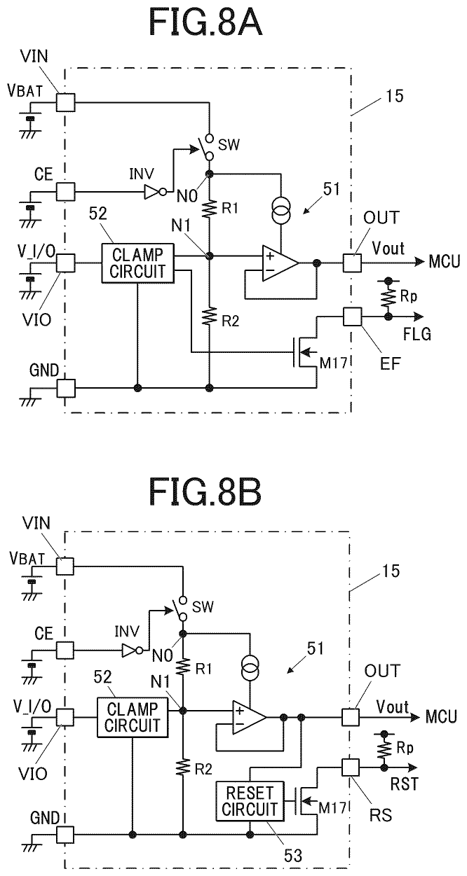

FIGS. 8A and 8B show other variations of the battery voltage monitoring IC 15 according to the embodiment in FIG. 2.

The variation of the battery voltage monitoring IC 15 shown in FIG. 8A includes an external terminal EF that outputs an error flag FLG, and an open drain NMOS S transistor M17 connected between the terminal EF and a grounding point. When the clamp circuit 52 clamps the potential at the connection node N1 of the resistors R1 and R2, the transistor M17 is turned on to output the error flag FLG from the external terminal EF.

A pull-up resistor Rp is connected to a transmission line connected to the external terminal EF. When the transistor M17 is turned on, a current is drawn from the pull-up resistor Rp, and a low-level signal is output to the microcomputer.

A signal for turning on the transistor M17 can be generated by providing, within the clamp circuit 52, a comparator that detects whether the clamp circuit 52 has started the clamp operation by comparing the potential at the node N5 in FIG. 4 with a predetermined reference voltage Vref, for example. Appropriately setting the reference voltage Vref allows the error flag FLG to be output when the input voltage VBAT becomes an overvoltage and the clamp operation is started.

On the other hand, the variation of the battery voltage monitoring IC 15 shown in FIG. 8B includes a reset circuit 53 that detects an abnormally low voltage state or the like to generate a reset signal, an external terminal RS that outputs a reset signal RST, and an open drain NMOS transistor M17 connected between the terminal RS and a grounding point. When the output of the voltage buffer circuit 51 falls below a predetermined voltage, the reset circuit 53 turns on the transistor M17 to output the reset signal RST from the external terminal RS.

The reset circuit 53 may include a comparator that detects whether the input voltage VBAT has reached an abnormally low voltage state or the like by comparing the output voltage of the voltage buffer circuit 51 with a predetermined reference voltage, for example.

Additionally, a variation is possible in which, along with the external terminal RS, transistor M17, and reset circuit 53 shown in FIG. 8B, the external terminal EF and transistor M17 shown in FIG. 8A, and a comparator that detects an overvoltage state are provided in the battery voltage monitoring IC 15.

The above describes one embodiment and its variants according to the present invention. However, the present invention is not limited to the above embodiment and variants, and various modifications can be made based on the technical idea of the present invention. For example, in the above embodiment, a battery voltage monitoring IC that includes MOS transistors has been described. However, the battery voltage monitoring IC may include bipolar transistors instead of the MOS transistors.

Furthermore, in the above embodiment, a case where the present invention is applied to an in-vehicle system has been described. However, the present invention can be applied to an electronic circuit system other than an in-vehicle system. Although embodiments of the present invention have been described and illustrated in detail, the disclosed embodiments are made for purposes of illustration and example only and not limitation. The scope of the present invention should be interpreted by terms of the appended claims.

According to the battery voltage monitoring semiconductor integrated circuit with the above configuration, a voltage proportional to the battery voltage, which is input to the voltage input terminal, is output from the voltage buffer circuit. This allows a microcomputer to perform constant monitoring, resulting in precise monitoring of the battery voltage. Furthermore, since the clamp circuit is provided, the voltage output from the voltage buffer circuit can be suppressed even when the battery voltage surges. Therefore, when a system is configured such that the output voltage of the voltage buffer circuit is input to the microcomputer, it is possible to prevent damage to an element of an I/O port of the microcomputer.

According to the present invention, it is possible to realize a battery voltage monitoring semiconductor integrated circuit that is capable of performing constant monitoring by a microcomputer and precise monitoring of a battery voltage, and an electronic circuit system that uses the same. In addition, there is an effect that it is possible to prevent damage to an element of an I/O port of the microcomputer when the battery voltage surges.

1. A battery voltage monitoring semiconductor integrated circuit, comprising:
a voltage input terminal to receive an input of a voltage from a monitored battery;
a voltage dividing circuit that includes a plurality of series resistors to divide a voltage at the voltage input terminal;
an output terminal that outputs a voltage corresponding to a voltage obtained by the voltage dividing circuit dividing the voltage at the voltage input terminal;
a voltage buffer circuit connected between a connection node of the plurality of series resistors and the output terminal; and
a clamp circuit that clamps a potential at the connection node of the plurality of series resistors.

2. The battery voltage monitoring semiconductor integrated circuit according to claim 1, wherein:
the clamp circuit includes:
a differential input stage that includes:
one input terminal to receive an input of a predetermined set voltage; and
another input terminal connected to the connection node of the plurality of series resistors; and
an output stage that includes:
a source follower circuit connected to an output node of the differential input stage; and
an output transistor having a control terminal to which an output of the source follower circuit is applied; and
the output transistor is connected between the connection node of the plurality of the series resistors constituting the voltage dividing circuit and a grounding point.

3. The battery voltage monitoring semiconductor integrated circuit according to claim 2, further comprising a first external terminal to receive an external input of the predetermined set voltage to be input to the one input terminal of the differential input stage.

4. The battery voltage monitoring semiconductor integrated circuit according to claim 2, further comprising a constant voltage circuit that generates the predetermined set voltage to be input to the one input terminal of the differential input stage.

5. The battery voltage monitoring semiconductor integrated circuit according to claim 1, further comprising:
a switch element connected in series with the plurality of series resistors constituting the voltage dividing circuit; and
a second external terminal capable of receiving a signal for turning on and off the switch element.

6. An electronic circuit system, comprising:
the battery voltage monitoring semiconductor integrated circuit according to claim 1; and
a microcomputer that includes:
an AD conversion circuit; and
an input terminal to receive an input of a voltage to be subject to AD conversion by the AD conversion circuit, wherein
a voltage output from the output terminal of the battery voltage monitoring semiconductor integrated circuit is input to the input terminal of the microcomputer.

7. An electronic circuit system, comprising:
the battery voltage monitoring semiconductor integrated circuit according to claim 2; and
a microcomputer that includes:
an AD conversion circuit; and
an input terminal to receive an input of a voltage to be subject to AD conversion by the AD conversion circuit, wherein
a voltage output from the output terminal of the battery voltage monitoring semiconductor integrated circuit is input to the input terminal of the microcomputer.

8. An electronic circuit system, comprising:
the battery voltage monitoring semiconductor integrated circuit according to claim 3; and
a microcomputer that includes:
an AD conversion circuit; and
an input terminal to receive an input of a voltage to be subject to AD conversion by the AD conversion circuit, wherein
a voltage output from the output terminal of the battery voltage monitoring semiconductor integrated circuit is input to the input terminal of the microcomputer.

9. An electronic circuit system, comprising:
the battery voltage monitoring semiconductor integrated circuit according to claim 4; and
a microcomputer that includes:
an AD conversion circuit; and
an input terminal to receive an input of a voltage to be subject to AD conversion by the AD conversion circuit, wherein
a voltage output from the output terminal of the battery voltage monitoring semiconductor integrated circuit is input to the input terminal of the microcomputer.

10. An electronic circuit system, comprising:
the battery voltage monitoring semiconductor integrated circuit according to claim 5; and
a microcomputer that includes:
an AD conversion circuit; and
an input terminal to receive an input of a voltage to be subject to AD conversion by the AD conversion circuit, wherein
a voltage output from the output terminal of the battery voltage monitoring semiconductor integrated circuit is input to the input terminal of the microcomputer.

11. An electronic circuit system, comprising:
the battery voltage monitoring semiconductor integrated circuit according to claim 3; and
a microcomputer that includes:
an AD conversion circuit; and
an input terminal to receive an input of a voltage to be subject to AD conversion by the AD conversion circuit, wherein
a voltage output from the output terminal of the battery voltage monitoring semiconductor integrated circuit is input to the input terminal of the microcomputer,
the predetermined set voltage is generated by the microcomputer, and
the predetermined set voltage generated is input to the first external terminal.

12. An electronic circuit system, comprising:
the battery voltage monitoring semiconductor integrated circuit according to claim 5; and
a microcomputer that includes:
an AD conversion circuit, and
an input terminal to receive an input of a voltage to be subject to AD conversion by the AD conversion circuit, wherein
a voltage output from the output terminal of the battery voltage monitoring semiconductor integrated circuit is input to the input terminal of the microcomputer,
the signal for turning on and off the switch element is generated by the microcomputer, and
the signal generated is input to the second external terminal.
